(19) United States
(12) Patent Application Publication
(10) Pub. No.: US 2025/0349772 A1
(43) Pub. Date: Nov. 13, 2025

(54) SEMICONDUCTOR STRUCTURE, PACKAGE STRUCTURE AND MANUFACTURING METHOD OF SEMICONDUCTOR STRUCTURE

(71) Applicant: Taiwan Semiconductor Manufacturing Company, Ltd., Hsinchu (TW)

(72) Inventors: Hao-Wen Ko, Hsinchu City (TW); Ping-Jung Wu, Hsinchu (TW); Tsang-Jiuh Wu, Hsinchu (TW); Jyu-Horng Shieh, Hsin-Chu (TW)

(73) Assignee: Taiwan Semiconductor Manufacturing Company, Ltd., Hsinchu (TW)

(21) Appl. No.: 18/662,983

(22) Filed: May 13, 2024

(51) Int. Cl. H01L 23/00; H01L 23/29; H01L 23/31; H01L 23/48; H10B 80/00

(52) U.S. Cl. CPC H01L 24/08; H01L 23/291; H01L 23/3121; H01L 24/96; H01L 23/481; H01L 24/16; H01L 2224/02165; H01L 2224/08235; H01L 2224/16245; H01L 2224/96; H01L 2924/351; H10B 80/00

(57) ABSTRACT

A semiconductor structure, a package structure and a manufacturing method of a semiconductor structure are provided. The semiconductor structure includes a first semiconductor die, a second semiconductor die and an insulating encapsulant. The second semiconductor die is overlapped with and electrically connected to the first semiconductor die. The insulating encapsulant is disposed on the second semiconductor die and at least laterally encapsulates the first semiconductor die. The first semiconductor die includes a first portion and a second portion located between the first portion and the second semiconductor die. In a sectional view, the second portion is wider than the first portion.

### BACKGROUND

In the existing die bonding processes, the flatness of the bonding surfaces is very important. In order to maintain the flatness of the bonding surface(s), the singulation process/method of the wafer shall to be properly selected. When the selected process/method cannot cut through metal, the test line area needs to include additional metal-free zones to facilitate the singulation process. However, the additional space in the test line area means less space for the semiconductor dies, which makes it difficult to increase the output of the semiconductor dies.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 to FIG. 9 are schematic sectional views illustrating a manufacturing method of a semiconductor structure according to some embodiments of the present disclosure.

FIG. 10 is a schematic sectional view of a package structure according to some embodiments of the present disclosure.

FIG. 11 is a schematic sectional view of a package structure according to some embodiments of the present disclosure.

FIG. 12 is a schematic sectional view of a package structure according to some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Dies (also referred to as “semiconductor dies”) can be singulated from a wafer through a singulation process, and the singulated die(s) can then be bonded to another wafer through a bonding process, such as a hybrid bonding process, etc. The flatness of the bonding surfaces affects the bonding result, and the flatness of the bonding surface of a singulated die is related to the selected singulation process. The existing singulation process includes a plasma dicing process, a laser grooving process, etc. The plasma dicing process can maintain the flatness of the bonding surface of a singulated die. However, the plasma dicing process cannot cut through metal. Because the scribe lines for the singulation process is in a test line area where test pads or other metal features are present, additional metal-free zones need to be included in the test line area to facilitate the singulation process. The laser grooving process can cut through metal, but it reduces the flatness of the bonding surfaces of the singulated dies, making the singulated dies unsuitable for hybrid bonding. If plasma dicing and laser grooving processes are performed sequentially from the bonding side of the wafer, and the opening/trench formed by laser grooving is smaller than the opening/trench formed by plasma dicing, the flatness of the bonding surfaces of the singulated dies can be maintained. However, the bonding side portion of a singulated die formed in the above manner will be narrower than the backside portion of the singulated die. After the singulated die is flipped and bonded to another die or wafer, a gap is between the two dies or between the die and the wafer due to the narrow at the bottom and wide at the top configuration of the singulated die. Since an insulating material formed through, for example, a CVD process is difficult to fill the gap, the reliability of the formed semiconductor structure is adversely affected.

In the present disclosure, after a first dicing process (e.g., a plasma dicing process or the like) is performed from a bonding side surface (also referred to as “front-side surface”) of a wafer to form at least one first trench, the wafer is flipped over, and then a second dicing process (e.g., a laser grooving process or the like) is performed from a backside surface of the wafer to form at least one second trench, wherein a width of the at least one second trench can be larger than or equal to a width of the at least one first trench. Through the above design, the flatness of the bonding surfaces of the singulated dies can be maintained. In addition, dies that are narrow at the top and wide at the bottom (that is, the bonding side portion is wider than the backside portion) or dies having a constant width can be formed through the above processes. The singulated die can then be picked up and placed on another wafer without a gap between the die and the wafer because of the narrow at the top and wide at the bottom configuration of the singulated die, which facilitates the formation of subsequent insulating material and/or improvement of the reliability of the formed semiconductor structure. Moreover, since the metal features in the wafer can be cut through the second dicing process (e.g., the laser grooving process or the like), metal-free zones in the existing test line area can be omitted, which helps increase the density or number of semiconductor die in the wafer.

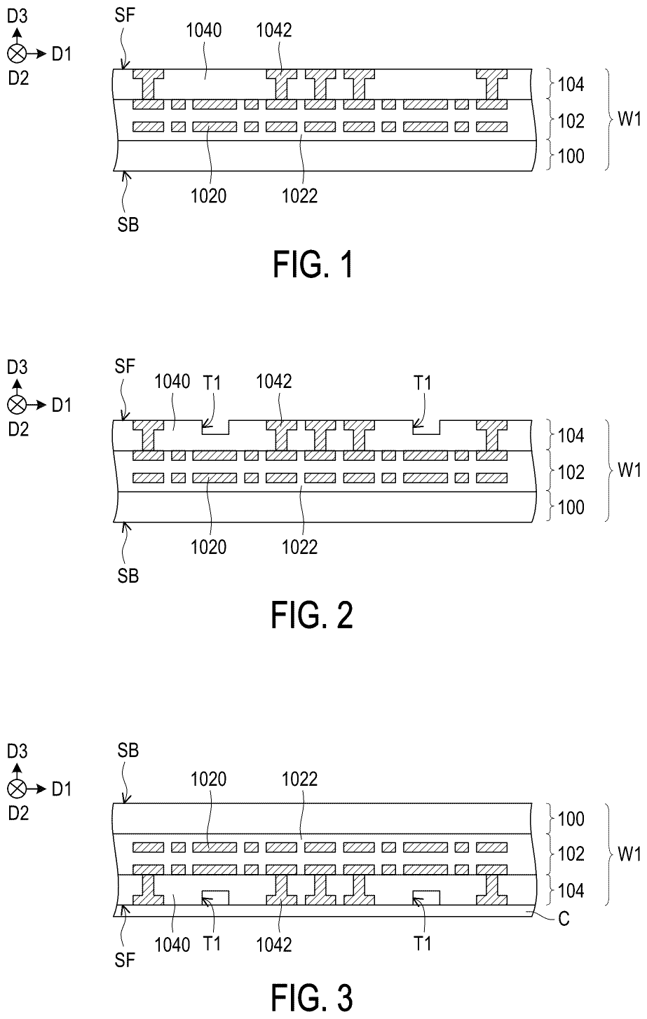

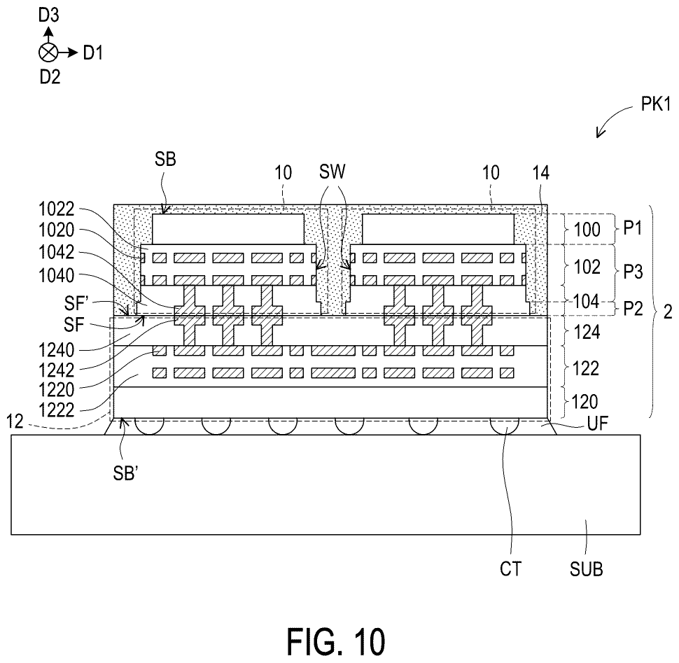

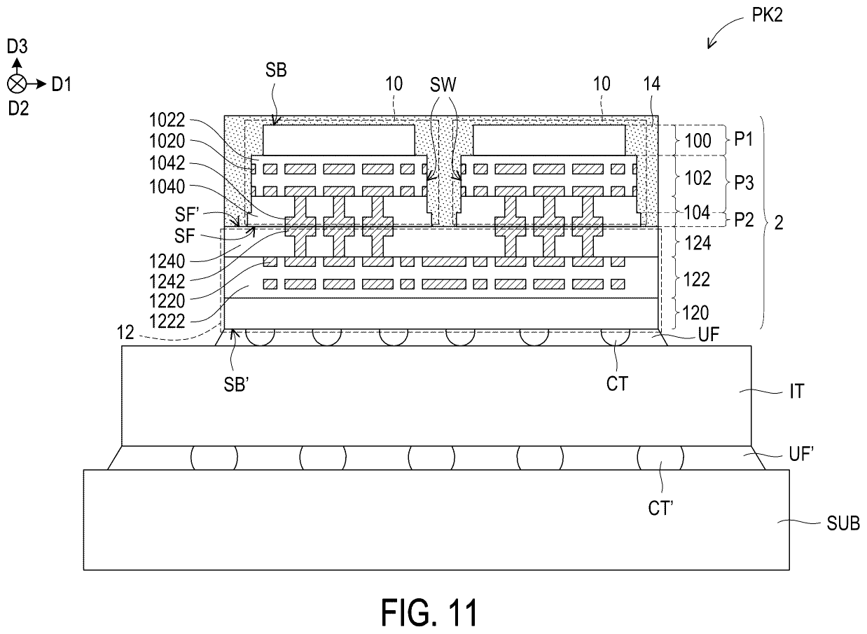

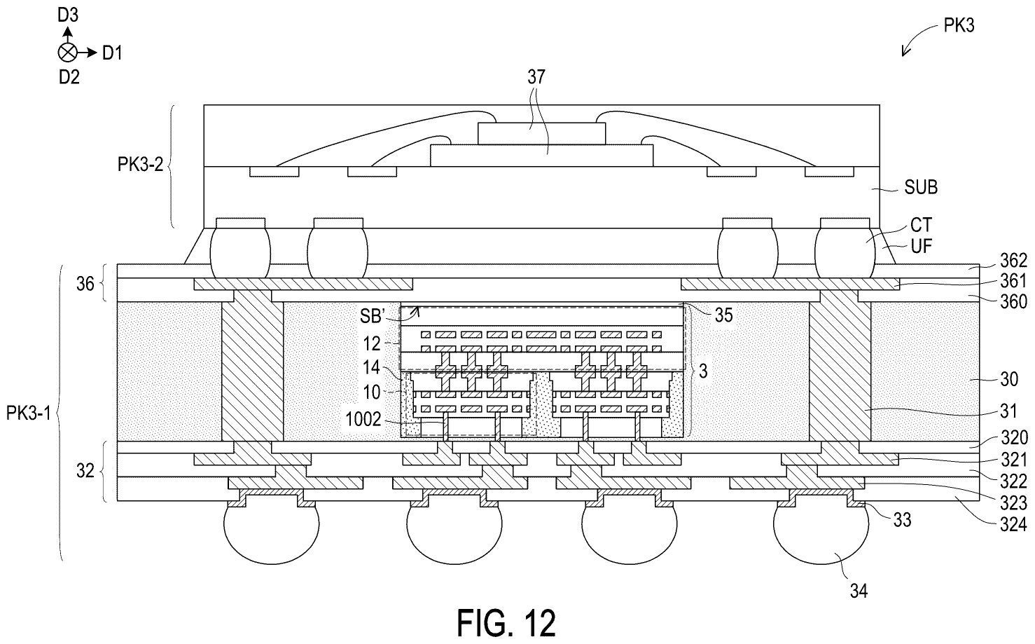

FIG. 1 to FIG. 9 are schematic sectional views illustrating a manufacturing method of a semiconductor structure according to some embodiments of the present disclosure. FIG. 10 is a schematic sectional view of a package structure according to some embodiments of the present disclosure. FIG. 11 is a schematic sectional view of a package structure according to some embodiments of the present disclosure. FIG. 12 is a schematic sectional view of a package structure according to some embodiments of the present disclosure.

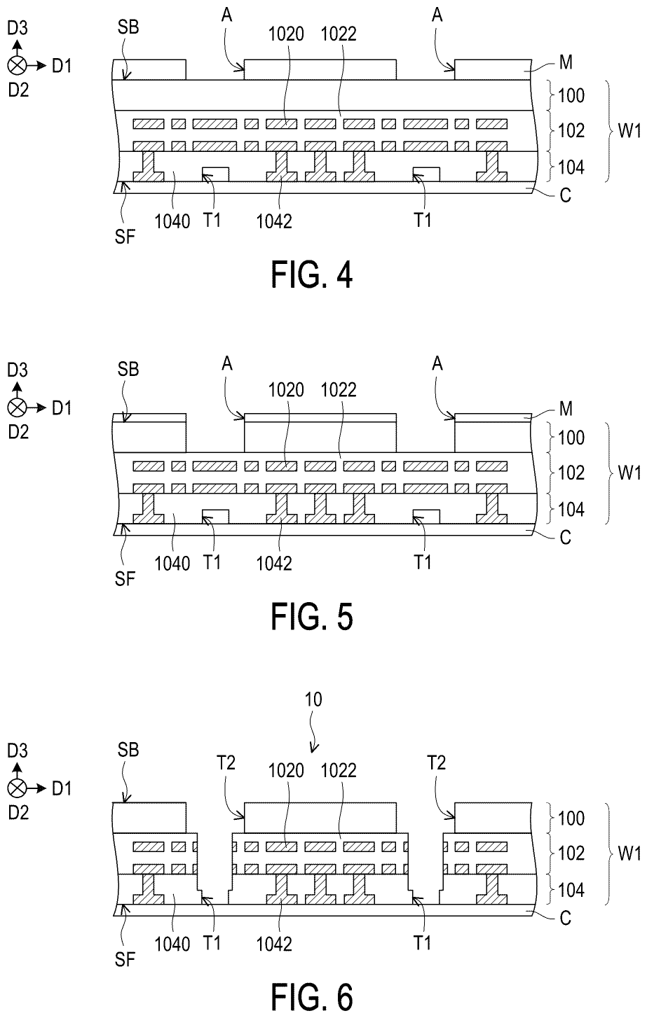

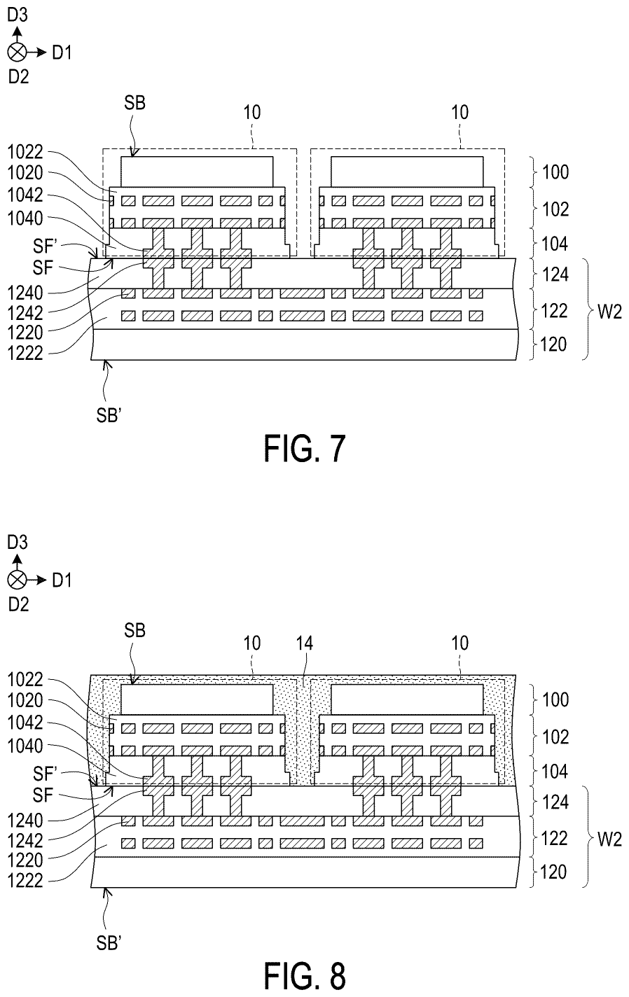

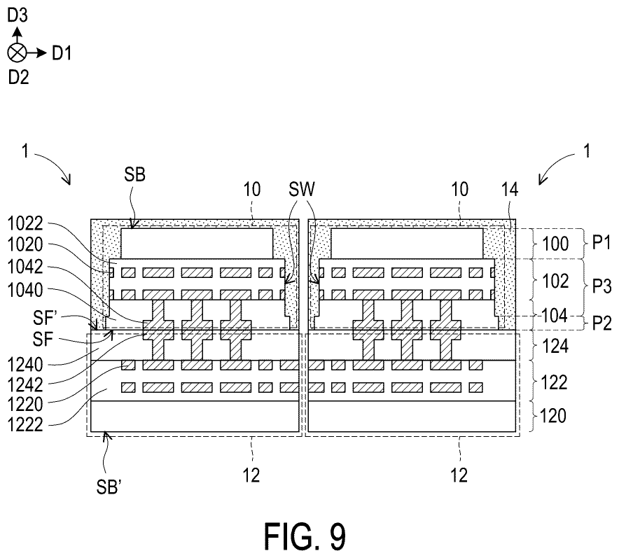

Referring to FIG. 1 to FIG. 9, a manufacturing method of a semiconductor structure 1 according to some embodiments of the present disclosure is provided. The manufacturing method of the semiconductor structure 1 includes: providing a first wafer W1 having a front-side surface SF and a backside surface SB opposite to the front-side surface SF, as shown in FIG. 1; forming at least one first trench T1 on the front-side surface SF of the first wafer W1, as shown in FIG. 2; flipping the first wafer W1, as shown in FIG. 3; forming at least one second trench T2 overlapped with and connected to the at least one first trench T1 on the backside surface SB to cut off the first wafer W1 to form a plurality of first semiconductor dies 10, as shown in FIG. 4 to FIG. 6; bonding at least one of the plurality of first semiconductor dies 10 to a second wafer W2, as shown in FIG. 7; and forming an insulating encapsulant 14 on the second wafer W2 to at least laterally encapsulating the at least one of the plurality of first semiconductor dies 10, as shown in FIG. 8. Optionally, in some embodiments, the manufacturing method of the semiconductor structure 1 further includes dicing the second wafer W2 to form a plurality of second semiconductor dies 12, as shown in FIG. 9.

In some embodiments, as shown in FIG. 1, the first wafer W1 includes a substrate 100, an interconnect structure 102 disposed on the substrate 100 and a bonding structure 104 disposed on the interconnect structure 102. The front-side surface SF of the first wafer W1 is, for example, a surface of the bonding structure 104 away from the interconnect structure 102. The backside surface SB of the first wafer W1 is, for example, a surface of the substrate 100 away from the interconnect structure 102.

The substrate 100 of the first wafer W1 may be or includes a monocrystalline semiconductor substrate such as a silicon substrate, a silicon-on-insulator (SOI) substrate, silicon-germanium on insulator (SGOI) or a germanium-on-insulator (GOI) substrate. In some embodiments, the substrate 100 is made of semiconductor materials, such as semiconductor materials of the groups III-V of the periodic table. In some embodiments, the substrate 100 includes elementary semiconductor materials such as silicon or germanium, compound semiconductor materials such as silicon carbide, gallium arsenide, indium arsenide, or indium phosphide or alloy semiconductor materials such as silicon germanium, silicon germanium carbide, gallium arsenide phosphide, or gallium indium phosphide.

In some embodiments, although not shown, the substrate 100 further includes active or passive devices, such as transistors, capacitors, resistors, or diodes formed therein. In some embodiments, although not shown, the substrate 100 further includes through substrate vias. The through substrate vias are formed by forming holes or recesses in the substrate 100 and then filling the recesses with a conductive material. In some embodiments, the recesses are formed by, for example, ctching, milling, laser drilling or the like. In some embodiments, the conductive material is formed by an electro-chemical plating process, chemical vapor deposition (CVD), atomic layer deposition (ALD) or physical vapor deposition (PVD), and the conductive material may include copper, tungsten, aluminum, silver, gold or a combination thereof.

The interconnect structure 102 overlies the substrate 100 and is electrically coupled between the substrate 100 (e.g., the through substrate vias) and the bonding structure 104. The interconnect structure 102 may include a plurality of wires 1020, a plurality of vias (not shown) and a dielectric layer 1022. Although not shown, the plurality of wires 1020 and the plurality of vias may be alternatingly stacked in the dielectric layer 1022, but not limited thereto. In some embodiments, the material of the plurality of wires 1020 and the plurality of vias includes copper or copper alloys. In some embodiments, the material of the dielectric layer 1022 includes silicon oxide, silicon nitride, silicon oxynitride, undoped silicate glass material or a suitable dielectric material.

The bonding structure 104 overlies the interconnect structure 102. The bonding structure 104 may include a bonding dielectric layer 1040 and a plurality of bonding conductors 1042 embedded in the bonding dielectric layer 1040. The bonding dielectric layer 1040 may include a plurality of contact openings, and the bonding conductors 1042 are exposed by the contact openings of the bonding dielectric layer 1040. In some embodiments, the bonding dielectric layer 1040 is formed through performing a chemical vapor deposition (CVD) process such as low-pressure CVD (LPCVD), plasma enhanced CVD (PECVD), and high-density plasma CVD (HDPCVD), and the material of the bonding dielectric layer 1040 includes silicon oxide, silicon nitride, silicon oxynitride, undoped silicate glass material or a suitable dielectric material. In some embodiments, the bonding conductors 1042 are conductive vias (e.g., copper vias), conductive pads (e.g., copper pads) or combinations thereof. In some embodiments, the bonding conductors 1042 are formed through performing deposition, plating, or other suitable processes, and the material of the bonding conductors 1042 includes aluminum, copper, alloys thereof or other suitable metallic material. In some embodiments, top surfaces of the bonding conductors 1042 are substantially level with a top surface of the bonding dielectric layer 1040.

Referring to FIG. 2, at least one first trench T1 is formed on the front-side surface SF of the first wafer W1. In some embodiments, the at least one first trench T1 is formed in the bonding structure 104 by removing a portion of the bonding dielectric layer 1040 between two adjacent bonding conductors 1042 among the plurality of bonding conductors 1042. In some embodiments, the portion of the bonding dielectric layer 1040 between the two adjacent bonding conductors 1042 is removed through a plasma dicing process. In some embodiments, a plurality of first trenches T1 are formed on the front-side surface SF of the first wafer W1, and the plurality of first trenches T1 are arranged in an array along a first direction D1 and a second direction D2 intersecting the first direction D1. In some embodiments, the first direction D1 is perpendicular to the second direction D2. In addition, the first direction D1 and the second direction D2 are both perpendicular to a thickness direction (e.g., a third direction D3) of the first wafer W1.

Referring to FIG. 3, after the at least one first trench T1 is formed, the first wafer W1 is flip over and placed on a carrier C. In some embodiments, the carrier C is a glass substrate, a ceramic carrier, or the like. In some embodiments, the carrier C has a round top-view shape and a size of a silicon wafer. In some embodiments, a de-bonding layer (not shown) is formed on the carrier C prior to placing the first wafer W1 on the carrier C. The de-bonding layer may be formed of a polymer-based material (e.g., a Light To Heat Conversion (LTHC) material). In some embodiments, the de-bonding layer is formed of an epoxy-based thermal-release material. In other embodiments, the de-bonding layer is formed of an ultra-violet (UV) glue. The de-bonding layer may be dispensed as a liquid and cured. In alternative embodiments, the de-bonding layer is a laminate film and is laminated onto the carrier C.

Referring to FIG. 4, a patterned mask M is formed on the first wafer W1. The patterned mask M includes at least one aperture AP overlapping the at least one first trench T1 and exposing a portion of the first wafer W1 to be removed in subsequent steps. The at least one aperture AP and the at least one first trench T1 are equal in number. In some embodiments, in a sectional view, as shown in FIG. 4, the at least one aperture AP is formed wider than the at least one first trench T1 to reduce the difficulty of aligning the at least one aperture AP and the at least one first trench T1 in the direction D3 or to make it easier to align the at least one aperture AP and the at least one first trench T1 in the direction D3. In other embodiments, in a sectional view, although not shown, the at least one aperture AP and the at least one first trench T1 are equal in width. In some embodiments, the patterned mask M is patterned through a laser grooving process, and the patterned mask M includes water soluble mask or the like.

Referring to FIG. 5, a portion of the substrate 100 overlapped with the at least one aperture AP of the patterned mask M is removed through, for example, a plasma dicing process, using the patterned mask M as a mask. In some embodiments, the patterned mask M is thinned through the plasma dicing process.

Referring to FIG. 6, a portion of the interconnect structure 102 overlapped with the at least one aperture AP of the patterned mask M as well as another portion of the bonding dielectric layer 1040 between the two adjacent bonding conductors 1042 and overlapped with the at least one aperture AP of the patterned mask M are both removed through, for example, a laser grooving process to form at least one second trench T2 connected to the at least one first trench T1 so as to cut off the first wafer W1 to form a plurality of first semiconductor dies 10. In some embodiments, the portion of the interconnect structure 102 and the another portion of the bonding dielectric layer 1040 that are removed through the laser grooving process are narrower than the portion of the substrate 100 removed through the plasma dicing process, so that the second trench T2 is wider in the substrate 100 than in the interconnect structure 102 and the bonding dielectric layer 1040. In other embodiments, although not shown, the portion of the interconnect structure 102 and the another portion of the bonding dielectric layer 1040 that are removed through the laser grooving process and the portion of the substrate 100 removed through the plasma dicing process are equal in width, so that the second trench T2 has a constant width in the substrate 100, the interconnect structure 102 and the bonding dielectric layer 1040. After the plurality of first semiconductor dies 10 are formed, the patterned mask M is removed.

In some alternative embodiments, although not shown, the at least one second trench T2 can be formed through a laser grooving process instead of the combination of a laser grooving process and another plasma dicing process.

Referring to FIG. 7, the at least one of the plurality of first semiconductor dies 10 is bonded to the second wafer W2 through a pick and place process and a hybrid bonding process. In some embodiments, the second wafer W2 includes a substrate 120, an interconnect structure 122 disposed on the substrate 120 and a bonding structure 124 disposed on the interconnect structure 122. A front-side surface SF′ of the second wafer W2 is, for example, a surface of the bonding structure 124 away from the interconnect structure 122. A backside surface SB′ of the second wafer W2 is, for example, a surface of the substrate 120 away from the interconnect structure 122.

The substrate 120, the interconnect structure 122, the bonding structure 124, a plurality of wires 1220 of the interconnect structure 122, a dielectric layer 1222 of the interconnect structure 122, a bonding dielectric layer 1240 of the bonding structure 124 and a plurality of bonding conductors 1242 of the bonding structure 124 may be similar to those previously discussed with reference to the substrate 100, the interconnect structure 102, the bonding structure 104, the plurality of wires 1020, the dielectric layer 1022, the bonding dielectric layer 1040 and the plurality of bonding conductors 1042, and will not be repeated here.

After the at least one of the plurality of first semiconductor dies 10 is placed on the second wafer W2, a hybrid bonding process that includes dielectric-to-dielectric bonding (e.g., the bonding between the bonding dielectric layer 1040 to the bonding dielectric layer 1240) and metal-to-metal bonding (e.g., the bonding between the plurality of bonding conductors 1042 to the plurality of bonding conductors 1242) is performed.

Referring to FIG. 8, an insulating encapsulant 14 is formed on the second wafer W2 through, for example, a CVD process. In some embodiments, the insulating encapsulant 14 laterally encapsulates the at least one of the plurality of first semiconductor dies 10. In some embodiments, the insulating encapsulant 14 further covers the at least one of the plurality of first semiconductor dies 10, i.e., the insulating encapsulant 14 may be thicker than the first semiconductor dies 10. In some embodiments, a material of the insulating encapsulant 14 includes an insulating material that can withstand 100 degrees Celsius or more. In some embodiments, the material of the insulating encapsulant 14 includes oxide, nitride, oxynitride, other insulating material that can withstand 100 degrees Celsius or more, or a combination thereof. By using insulating material that can withstand 100 degrees Celsius or more instead of an underfill material that can withstand less than 100 degrees Celsius to encapsulate the at least one of the plurality of first semiconductor dies 10, the insulating encapsulant 14 can withstand high temperature subsequent processes (if needed, e.g., for multi die stacking, solder ball mounting or etc.), thereby helping to improve the reliability of the overall structure.

Optionally, in some embodiments, as shown in FIG. 9, the manufacturing method of the semiconductor structure 1 further includes dicing the second wafer W2 through at least one of the dicing methods described above to form a plurality of second semiconductor dies 12. Each of the plurality of second semiconductor dies 12 may be hybrid bonded to one or more of the plurality of first semiconductor dies 10.

After the singulation of the second wafer W2, a plurality of semiconductor structures 1 are formed. In the manufacturing method described above, after a first dicing process (e.g., a plasma dicing process or other process that can maintain the flatness of the bonding surface) is performed from the front-side surface SF of the first wafer W1 to form at least one first trench T1, the first wafer W1 is flipped over, and then a second dicing process (e.g., a laser grooving process or other process that can cut through metal) is performed from the backside surface SB of the first wafer W1 to form at least one second trench T2, wherein a width of the at least one second trench T2 can be larger than or equal to a width of the at least one first trench T1. Through the above design, the flatness of the bonding surfaces (the front-side surfaces SF) of the singulated dies (the plurality of first semiconductor dies 10) can be maintained. In addition, the plurality of first semiconductor dies 10 are narrow at the top and wide at the bottom, or have a constant width. Therefore, the first semiconductor die(s) 10 can be bonded to the second wafer W2 without a gap between the first semiconductor die(s) 10 and the second wafer W2, which facilitates the formation of subsequent insulating material and/or improvement of the reliability of the formed semiconductor structure 1. Moreover, since the metal features in the first wafer W1 can be cut through the second dicing process (e.g., the laser grooving process or other process that can cut through metal), metal-free zones in the existing test line area can be omitted, which helps increase the density or number of semiconductor dies in the first wafer W1.

As shown in FIG. 9, each of the plurality of semiconductor structures 1 may include a first semiconductor die 10, a second semiconductor die 12 and an insulating encapsulant 14. The second semiconductor die 12 is overlapped with and electrically connected to the first semiconductor die 10. The insulating encapsulant 14 is disposed on the second semiconductor die 12 and at least laterally encapsulates the first semiconductor die 10. The first semiconductor die 10 includes a first portion P1 and a second portion P2 located between the first portion P1 and the second semiconductor die 12. In a sectional view, as shown in FIG. 9, the second portion P2 is wider than the first portion P1.

In some embodiments, as shown in FIG. 9, the first semiconductor die 10 further includes a third portion P3 located between the first portion P1 and the second portion P2, and in the sectional view, the third portion P3 is wider than the first portion P1 and narrower than the second portion P2. In other embodiments in which the second trench T2 (see FIG. 6) has a constant width in the substrate 100, the interconnect structure 102 and the bonding dielectric layer 1040, the first semiconductor die 10 includes the first portion P1 and the second portion P2 and does not include the third portion P3.

In some embodiments, as shown in FIG. 9, at least one side wall SW of the first semiconductor die 10 includes at least one truncated conductive line (e.g., at least one truncated wire 1020). Specifically, since the second trench formation process includes a process (e.g., a laser grooving process as mentioned in FIG. 6) that can cut through metal, metal-free zones in the existing test line area can be omitted, and the wire 1020 truncated during the second trench formation process can be seen on at least one side wall SW of the first semiconductor die 10.

In other embodiments, although not shown in FIG. 9, in at least one of the plurality of semiconductor structures 1, the second semiconductor die 12 can be hybrid bonded with more than one first semiconductor dies 10.

In some embodiments, the first semiconductor die 10 and the second semiconductor die 12 are the same type of dies or perform the same functions. In other embodiments, the first semiconductor die 10 and the second semiconductor die 12 are different types of dies or perform different functions. In some embodiments, the first semiconductor die 10 and the second semiconductor die 12 include logic dies, such as central processing unit (CPU) dies, graphic processing unit (GPU) dies, micro control unit (MCU) dies, input-output (I/O) dies, baseband (BB) dies, application processor (AP) dies or the like. In some embodiments, the first semiconductor die 10 and the second semiconductor die 12 include memory dies such as high bandwidth memory dies. In some embodiments, the first semiconductor die 10 and the second semiconductor die 12 include an electronic integrated circuit (EIC) die and a photonic integrated circuit (PIC) die.

Referring to FIG. 10, a package structure PK1 according to some embodiments of the present disclosure is provided. The package structure PK1 includes a substrate SUB and a semiconductor structure 2 electrically connected to the substrate SUB. The semiconductor structure 2 includes a first semiconductor die 10, a second semiconductor die 12 and an insulating encapsulant 14. The second semiconductor die 12 is disposed between the first semiconductor die 10 and the substrate SUB and electrically connected to the first semiconductor die 10. The insulating encapsulant 14 is disposed on the second semiconductor die 12 and at least laterally encapsulates the first semiconductor die 10. The first semiconductor die 10 includes a first portion P1 and a second portion P2 located between the first portion P1 and the second semiconductor die 12. In a sectional view, as shown in FIG. 10, the second portion P2 is wider than the first portion P1.

In some embodiments, the semiconductor structure 2 includes two first semiconductor dies 10 hybrid bonded to the second semiconductor die 12. In some embodiments, the first semiconductor die 10 further includes a third portion P3 located between the first portion P1 and the second portion P2, and in the sectional view, the third portion P3 is wider than the first portion P1 and narrower than the second portion P2. In other embodiments in which the second trench T2 (see FIG. 6) has a constant width in the substrate 100, the interconnect structure 102 and the bonding dielectric layer 1040, the first semiconductor die 10 includes the first portion P1 and the second portion P2 and does not include the third portion P3. In some embodiments, at least one side wall SW of the first semiconductor die 10 includes at least one truncated conductive line (e.g., at least one truncated wire 1020).

In some embodiments, the semiconductor structure 2 is bonded to the substrate SUB through a plurality of conductive terminals CT. The plurality of conductive terminals CT include lead-free solder balls, solder balls, ball grid array (BGA) balls, bumps, C4 bumps or micro bumps. The substrate SUB may be a package substrate, a circuit board, a silicon interposer, an organic interposer, or the like. In some embodiments, an underfill UF is disposed between the semiconductor structure 2 and the substrate SUB to protect the plurality of conductive terminals CT against thermal or physical stresses and to secure the electrical connection of the substrate SUB with the semiconductor structure 2. In some embodiments, the underfill UF is formed by capillary underfill filling (CUF). A dispenser (not shown) may apply a filling material (not shown) along the perimeter of the semiconductor structure 2. In some embodiments, a heating process is performed to let the filling material penetrate in the interstices defined by the plurality of connectors 16 between the substrate SUB and the semiconductor structure 2 by capillarity. In some embodiments, a curing process is performed to consolidate the underfill UF.

In some embodiments, although not shown, a heat dissipation device can be disposed on the semiconductor structure 2, and the semiconductor structure 2 is disposed between the heat dissipation device and the substrate SUB.

Referring to FIG. 11, a package structure PK2 according to some embodiments of the present disclosure is provided. The package structure PK2 is, for example, a chip-on-wafer-on-substrate (CoWoS) structure.

Specifically, the package structure PK2 may include the semiconductor structure 2, an interposer IT and the substrate SUB, wherein the interposer IT electrically connects the semiconductor structure 2 to the substrate SUB. In some embodiments, the semiconductor structure 2 is bonded to the interposer IT through the plurality of conductive terminals CT. The interposer IT may be a silicon interposer, an organic interposer, or the like. In some embodiments, the underfill UF is disposed between the semiconductor structure 2 and the interposer IT. In some embodiments, the interposer IT is bonded to the substrate SUB through a plurality of conductive terminals CT′. The plurality of conductive terminals CT′ may be made of a conductive material similar to those previously discussed with reference to the plurality of conductive terminals CT, and will not be repeated here. In some embodiments, an underfill UF′ is disposed between the interposer IT and the substrate SUB. The underfill UF′ may be made of a material similar to those previously discussed with reference to the underfill UF, and will not be repeated here. The substrate SUB may be a package substrate, a circuit board, or the like.

Referring to FIG. 12, a package structure PK3 according to some embodiments of the present disclosure is provided. The package structure PK3 is, for example, a package on package (POP) structure. Specifically, the package structure PK3 includes a package PK3-1 and a package PK3-2 disposed on the package PK3-1.

In some embodiments, the package PK3-1 includes a semiconductor structure 3, an insulating encapsulant 30, a plurality of conductive through vias 31, a first redistribution circuit structure 32, under-bump metallurgies (UBMs) 33, a plurality of connectors 34, a die-attachment film 35 and a second redistribution circuit structure 36.

In the semiconductor structure 3, the first semiconductor die 10 further includes a plurality of through substrate vias 1002 that electrically connects the first semiconductor die 10 to the first redistribution circuit structure 32. The semiconductor structure 3 and the plurality of conductive through vias 31 are embedded in the insulating encapsulant 30. The material of the plurality of conductive through vias 32 may include copper, aluminum, or the like. The plurality of conductive through vias 32 may have the shape of rods. The top-view shapes of the plurality of conductive through vias 72 may be circles, rectangles, squares, hexagons, or the like. The insulating encapsulant 30 may be made of a molding compound (e.g., epoxy or other suitable resin). The insulating encapsulant 30 fills the gaps between neighboring conductive through vias 72, the gaps between the semiconductor structure 3 and the plurality of conductive through vias 72.

The first redistribution circuit structure 32 is disposed on lower surfaces of the insulating encapsulant 30 and the plurality of conductive through vias 31 and electrically connected to the semiconductor structure 3 and the plurality of conductive through vias 31. In some embodiments, the first redistribution circuit structure 32 includes a dielectric layer 320, redistribution wirings 321, a dielectric layer 322, redistribution wirings 323, and a dielectric layer 324 sequentially formed on the lower surfaces of the insulating encapsulant 30 and the plurality of conductive through vias 31.

In some embodiments, the dielectric layer 320, the dielectric layer 322 and the dielectric layer 324 are formed of a polymer such as PBO, polyimide, or the like. In some alternative embodiments, the dielectric layer 320, the dielectric layer 322 and the dielectric layer 324 are formed of non-organic dielectric materials such as silicon oxide, silicon nitride, silicon carbide, silicon oxynitride, or the like. In some embodiments, each of the redistribution wirings 321 and the redistribution wirings 323 includes metal traces (metal lines) over a corresponding dielectric layer as well as metal vias penetrate through the corresponding dielectric layer. In some embodiments, the redistribution wirings 321 and the redistribution wirings 323 are formed through a plating process, wherein each of the redistribution wirings includes a seed layer (not shown) and a plated metallic material over the seed layer. The seed layer and the plated material may be formed of the same material or different materials. The redistribution wirings may include a metal or a metal alloy including aluminum, copper, tungsten, and alloys thereof.

The under-bump metallurgies 33 are formed in the openings of the dielectric layer 324 through, for example, deposition and patterning processes. The plurality of connectors 34 may be formed on the under-bump metallurgies 33 by placing solder on the under-bump metallurgies 33 and then reflowing the solder to form solder balls. Alternatively, the plurality of connectors 34 may be formed through a plating process.

The semiconductor structure 3 is attached to the second redistribution circuit structure 36 through the die-attachment film 35. The die-attachment film 35 is an adhesive film, such as an epoxy film, a silicone film and so on.

The second redistribution circuit structure 36 is disposed on upper surfaces of the insulating encapsulant 30 and the plurality of conductive through vias 31 and electrically connected to the plurality of conductive through vias 31, the first redistribution circuit structure 32 and the semiconductor structure 3. In some embodiments, the second redistribution circuit structure 36 includes a dielectric layer 360, redistribution wirings 361 and a dielectric layer 362 sequentially formed on the upper surfaces of the insulating encapsulant 30 and the plurality of conductive through vias 31.

In some embodiments, the dielectric layer 360 and the dielectric layer 362 are formed of a polymer, which may also be a photo-sensitive material such as polybenzoxazole (PBO), polyimide, benzocyclobutene (BCB), or the like, which may be easily patterned using a photolithography process. In other embodiments, the dielectric layer 360 and the dielectric layer 362 are formed of a nitride such as silicon nitride, an oxide such as silicon oxide, phosphosilicate glass (PSG), borosilicate glass (BSG), Boron-doped phosphosilicate glass (BPSG), or the like. The formation of the redistribution wirings 361 may include forming a seed layer (not shown) over the dielectric layer 360, forming a patterned mask (not shown) such as a photoresist layer over the seed layer, and then performing a plating process on the exposed seed layer. The patterned mask and the portions of the seed layer covered by the patterned mask are then removed, leaving the redistribution wirings 361 as shown in FIG. 12. In some embodiments, the seed layer includes a titanium layer and a copper layer over the titanium layer. The seed layer may be formed using, for example, physical vapor deposition (PVD). The plating may be performed using, for example, electroless plating. FIG. 12 illustrates the second redistribution circuit structure 36 having single-layer redistribution wirings 361 for illustrative purposes and some embodiments may have a plurality of layers of redistribution wirings 361 by repeating the process discussed above.

The dielectric layer 362 is then patterned to form a plurality of openings therein.

Hence, portions of the redistribution wirings 361 are exposed through the plurality of openings in the dielectric layer 362. The package PK3-2 is bonded to the package PK3-1 through a plurality of conductive terminals CT. The plurality of conductive terminals CT are formed in the plurality of openings in the dielectric layer 362. In some embodiments, an underfill UF is formed between the package PK3-2 and the package PK3-1.

In some embodiments, the package PK3-2 includes device dies 37, which may be memory dies such as static random access memory (SRAM) dies, dynamic random access memory (DRAM) dies, or the like. The memory dies may also be bonded to the substrate SUB in some exemplary embodiments. The device dies 37 are electrically connected to the semiconductor structure 3 through the substrate SUB, the plurality of conductive terminals CT, the second redistribution circuit structure 36, the plurality of conductive through vias 31 and the first redistribution circuit structure 32.

Based on the above discussions, it can be seen that the present disclosure offers various advantages. It is understood, however, that not all advantages are necessarily discussed herein, and other embodiments may offer different advantages, and that no particular advantage is required for all embodiments.

According to some embodiments, a semiconductor structure includes a first semiconductor die, a second semiconductor die and an insulating encapsulant. The second semiconductor die is overlapped with and electrically connected to the first semiconductor die. The insulating encapsulant is disposed on the second semiconductor die and at least laterally encapsulates the first semiconductor die. The first semiconductor die includes a first portion and a second portion located between the first portion and the second semiconductor die. In a sectional view, the second portion is wider than the first portion. In some embodiments, the second semiconductor die is hybrid bonded to the first semiconductor die. In some embodiments, a material of the insulating encapsulant includes an insulating material that can withstand 100 degrees Celsius or more. In some embodiments, the material of the insulating encapsulant comprises oxide, nitride or oxynitride. In some embodiments, the first semiconductor die further includes a third portion located between the first portion and the second portion, and in the sectional view, the third portion is wider than the first portion and narrower than the second portion. In some embodiments, at least one side wall of the first semiconductor die includes at least one truncated conductive line.

According to some embodiments, a package structure includes a substrate and a semiconductor structure electrically connected to the substrate. The semiconductor structure includes a first semiconductor die, a second semiconductor die and an insulating encapsulant. The second semiconductor die is disposed between the first semiconductor die and the substrate and electrically connected to the first semiconductor die. The insulating encapsulant is disposed on the second semiconductor die and at least laterally encapsulates the first semiconductor die. The first semiconductor die includes a first portion and a second portion located between the first portion and the second semiconductor die. In a sectional view, the second portion is wider than the first portion. In some embodiments, the package structure is a package on package (POP) structure or a chip-on-wafer-on-substrate (CoWoS) structure. In some embodiments, the second semiconductor die is hybrid bonded to the first semiconductor die. In some embodiments, a material of the insulating encapsulant includes an insulating material that can withstand 100 degrees Celsius or more. In some embodiments, the material of the insulating encapsulant includes oxide, nitride or oxynitride. In some embodiments, the first semiconductor die further includes a third portion located between the first portion and the second portion, and in the sectional view, the third portion is wider than the first portion and narrower than the second portion. In some embodiments, at least one side wall of the first semiconductor die includes at least one truncated conductive line.

According to some embodiments, a manufacturing method of a semiconductor structure includes: providing a first wafer having a front-side surface and a backside surface opposite to the front-side surface; forming at least one first trench on the front-side surface of the first wafer; flipping the first wafer; forming at least one second trench overlapped with and connected to the at least one first trench on the backside surface to cut off the first wafer to form a plurality of first semiconductor dies; bonding at least one of the plurality of first semiconductor dies to a second wafer; and forming an insulating encapsulant on the second wafer to at least laterally encapsulating the at least one of the plurality of first semiconductor dies. In some embodiments, the first wafer includes a substrate, an interconnect structure disposed on the substrate and a bonding structure disposed on the interconnect structure, and the at least one first trench is formed in the bonding structure. In some embodiments, the bonding structure includes a bonding dielectric layer and a plurality of bonding conductors embedded in the bonding dielectric layer, and the at least one first trench is formed by removing a portion of the bonding dielectric layer between two adjacent bonding conductors among the plurality of bonding conductors. In some embodiments, the portion of the bonding dielectric layer between the two adjacent bonding conductors is removed through a plasma dicing process. In some embodiments, the at least one second trench is formed by removing another portion of the bonding dielectric layer between the two adjacent bonding conductors, a portion of the interconnect structure overlapped with the at least one first trench and a portion of the substrate overlapped with the at least one first trench. In some embodiments, the another portion of the bonding dielectric layer between the two adjacent bonding conductors, the portion of the interconnect structure overlapped with the at least one first trench and the portion of the substrate overlapped with the at least one first trench are removed through at least one of a laser grooving process and another plasma dicing process. In some embodiments, the at least one of the plurality of first semiconductor dies is bonded to the second wafer through a pick and place process and a hybrid bonding process.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a first semiconductor die;
a second semiconductor die overlapped with and electrically connected to the first semiconductor die; and
an insulating encapsulant disposed on the second semiconductor die and at least laterally encapsulating the first semiconductor die, wherein:
the first semiconductor die comprises a first portion and a second portion located between the first portion and the second semiconductor die, and
in a sectional view, the second portion is wider than the first portion.

2. The semiconductor structure as claimed in claim 1, wherein the second semiconductor die is hybrid bonded to the first semiconductor die.

3. The semiconductor structure as claimed in claim 1, wherein a material of the insulating encapsulant comprises an insulating material that can withstand 100 degrees Celsius or more.

4. The semiconductor structure as claimed in claim 1, wherein the material of the insulating encapsulant comprises oxide, nitride or oxynitride.

5. The semiconductor structure as claimed in claim 1, wherein the first semiconductor die further comprises a third portion located between the first portion and the second portion, and in the sectional view, the third portion is wider than the first portion and narrower than the second portion.

6. The semiconductor structure as claimed in claim 1, wherein at least one side wall of the first semiconductor die comprises at least one truncated conductive line.

7. A package structure, comprising:
a substrate; and
a semiconductor structure electrically connected to the substrate, wherein the semiconductor structure comprises:
a first semiconductor die;
a second semiconductor die disposed between the first semiconductor die and the substrate and electrically connected to the first semiconductor die; and
an insulating encapsulant disposed on the second semiconductor die and at least laterally encapsulating the first semiconductor die, wherein:
the first semiconductor die comprises a first portion and a second portion located between the first portion and the second semiconductor die, and
in a sectional view, the second portion is wider than the first portion.

8. The package structure as claimed in claim 7, wherein the package structure is a package on package (POP) structure or a chip-on-wafer-on-substrate (CoWoS) structure.

9. The package structure as claimed in claim 7, wherein the second semiconductor die is hybrid bonded to the first semiconductor die.

10. The package structure as claimed in claim 7, wherein a material of the insulating encapsulant comprises an insulating material that can withstand 100 degrees Celsius or more.

11. The package structure as claimed in claim 7, wherein the material of the insulating encapsulant comprises oxide, nitride or oxynitride.

12. The package structure as claimed in claim 7, wherein the first semiconductor die further comprises a third portion located between the first portion and the second portion, and in the sectional view, the third portion is wider than the first portion and narrower than the second portion.

13. The package structure as claimed in claim 7, wherein at least one side wall of the first semiconductor die comprises at least one truncated conductive line.

14. A manufacturing method of a semiconductor structure, comprising:
providing a first wafer having a front-side surface and a backside surface opposite to the front-side surface;
forming at least one first trench on the front-side surface of the first wafer;
flipping the first wafer;
forming at least one second trench overlapped with and connected to the at least one first trench on the backside surface to cut off the first wafer to form a plurality of first semiconductor dies;
bonding at least one of the plurality of first semiconductor dies to a second wafer; and
forming an insulating encapsulant on the second wafer to at least laterally encapsulating the at least one of the plurality of first semiconductor dies.

15. The manufacturing method of the semiconductor structure as claimed in claim 14, wherein the first wafer comprises a substrate, an interconnect structure disposed on the substrate and a bonding structure disposed on the interconnect structure, and the at least one first trench is formed in the bonding structure.

16. The manufacturing method of the semiconductor structure as claimed in claim 15, wherein the bonding structure comprises a bonding dielectric layer and a plurality of bonding conductors embedded in the bonding dielectric layer, and the at least one first trench is formed by removing a portion of the bonding dielectric layer between two adjacent bonding conductors among the plurality of bonding conductors.

17. The manufacturing method of the semiconductor structure as claimed in claim 16, wherein the portion of the bonding dielectric layer between the two adjacent bonding conductors is removed through a plasma dicing process.

18. The manufacturing method of the semiconductor structure as claimed in claim 16, wherein the at least one second trench is formed by removing another portion of the bonding dielectric layer between the two adjacent bonding conductors, a portion of the interconnect structure overlapped with the at least one first trench and a portion of the substrate overlapped with the at least one first trench.

19. The manufacturing method of the semiconductor structure as claimed in claim 17, wherein the another portion of the bonding dielectric layer between the two adjacent bonding conductors, the portion of the interconnect structure overlapped with the at least one first trench and the portion of the substrate overlapped with the at least one first trench are removed through at least one of a laser grooving process and another plasma dicing process.

20. The manufacturing method of the semiconductor structure as claimed in claim 14, wherein the at least one of the plurality of first semiconductor dies is bonded to the second wafer through a pick and place process and a hybrid bonding process.
